(19) United States
(12) Patent Application Publication
(10) Pub. No.: US 2009/0174415 A1
(43) Pub. Date: Jul. 9, 2009

(54) Method for Calibrating a Real-Time Load-Pull System

(76) Inventors: Jan Verspecht, Opwijk (BE); Fabien De Groote, Brive (FR)

Correspondence Address: JAN VERSPECHT B.V.B.A., MECHELSTRAAT 17, OPWIJK, B-1745, BE

(21) Appl. No.: 11/969,895

(22) Filed: Jan. 5, 2008

(51) Int. Cl. G01R 27/06

(52) U.S. Cl. 324/601

(57) ABSTRACT

A calibration procedure for a real-time load-pull system whereby the signal passes through at least one of the tuners of said real-time load-pull system. A calibration standard is connected to the test ports and an electromagnetic wave signal passes through one of the tuners before passing through the wave sensing structure. After having passed the wave sensing structure the electromagnetic wave signal interacts with the calibration element. This results in a reflected and eventually a transmitted electromagnetic wave signal that pass through the wave sensing structures of the system. The sensed electromagnetic wave signals are measured by means of a receiver. The procedure is repeated with different calibration standards. Then a line element is connected to the test ports and, one after the other, a set of calibration standards, a power meter and a harmonic phase reference generator are connected to the output tuner, each time sending a signal and measuring the wave signals. The measured data is used to calculate the error coefficients of the real-time load-pull system.

### CROSS-REFERENCE TO RELATED APPLICATIONS

Not Applicable

### FEDERALLY SPONSORED RESEARCH

Not Applicable

### SEQUENCE LISTING OR PROGRAM

Not Applicable

### BACKGROUND OF THE INVENTION

1. Field of Invention

The present invention relates to the measurement of incident and reflected waveforms for microwave and radio-frequency (RF) devices-under-test (DUTs) under realistic large signal operating conditions.

2. Description of the Related Art

Modern wireless telecommunication systems use complex signals at high carrier frequencies, with frequencies typically in the GHz range. These signals are generated by electrical circuitry, like e.g. modulators and mixers that can typically only handle low power levels in the milliwatt range. The generated low power signals are amplified to a higher power level before being sent to the antenna. At the antenna power levels range from about 1 Watt for a cellular phone to about 100 Watt for a base station. The amplification of the signals is performed by means of high frequency power amplifiers. These amplifiers contain one or more high frequency power transistors. In order to build a good amplifier the designer needs a detailed knowledge of the behavior of the high frequency power transistors under a wide range of realistic operating conditions. The knowledge of the transistor behavior is gained by using microwave measurement systems and methods that allow to emulate such realistic operating conditions and that allow to measure the input and output signals at the terminals of the transistor under these realistic operating conditions. Measurements whereby one emulates realistic operating conditions are often called load-pull measurements, since in most cases the emulation of realistic operating conditions corresponds to presenting a whole range of impedances or “loads” at the transistor output terminal. In some cases one does not only change the output impedance seen by the transistor output terminal, but one also changes the impedance of the signal source that is connected to the input terminal, this is called source-pull.

An example of a common and simple load-pull system, together with its calibration procedure, is described in “Basic Verification of Power Loadpull Systems,” by John Sevic, Application Note 5C-055 of the Maury Microwave Corporation, 1 Oct. 2004. Such a common and simple load-pull system is schematically depicted in FIG. 1. Note that in all of the following, the bias circuitry that is always present to provide direct current or voltage to the device-under-test is systematically omitted for reasons of providing more clarity to both the text and the figures. In such a simple load-pull system the controllable output impedance is provided by an output tuner 15 that is connected as close as possible to the output terminal of the device-under-test 14, usually a power transistor. The output signal generated by the device-under-test 14 passes through the output tuner 15 and is measured by a receiver 17, like a spectrum analyzer, a vector network analyzer or a power sensor 29. The output signal at the terminal of the device-under-test 14, before it passed through the tuner, is calculated by using the value measured by the receiver 17 as well as the S-parameter characteristic of the output tuner 15. As such the above common and simple load-pull method requires an accurate a priori S-parameter characterization of the tuner, and this for all possible impedance settings of the output tuner 15 at which one wants to perform a load-pull measurement. This necessary a priori S-parameter characterization of tuners is very time consuming and often leads to significant measurement errors because of potential measurement inaccuracies. The tuner characterization issue has been resolved by the insertion of a wave sensing structure 13 between the device-under-test 14 terminal and the output tuner 15, respectively the input tuner 21. Such a more advanced load-pull system is depicted in FIG. 2. The wave sensing structure 13 is connected to a receiver 17. The wave sensing structure is a piece of hardware that enables to sense the incident and the reflected waves that are traveling through an electromagnetic waveguiding structure. In prior art different types of wave sensing structures are being used. The most common wave sensing structure is a distributed dual directional coupler, other sensing structures used in prior art are a loop type coupler (U.S. Pat. No. 7,282,926 B1 by Verspecht et al.), or a combination of an electrical field probe and a magnetic field probe (US 2006/0279275 A1 by Simpson). The wave sensing structure and the tuner can be combined into one apparatus (U.S. Pat. No. 7,282,926 B1 by Verspecht et al., US 2006/0279275 A1 by Simpson). Once calibrated, the output wave sensing structure 13, respectively the input wave sensing structure 12, and the receiver 17 have the full functionality of a reflectometer. This allows to measure the tuner characteristic in real time, during the actual load-pull measurement, thereby eliminating the need for a costly a priori characterization of the system tuners. Because of the above capability such an advanced load-pull measurement system is called a real-time load-pull system. A good description can be found in the paper “Recent Improvements in Real-Time Load-Pull Systems,” authored by Andrea Ferrero et al., Conference Record of the IMTC 2006—Instrumentation and Measurement Technology Conference, Sorrento, Italy, pp. 448-451, April 2006. One of the main challenges of any real-time load-pull system is the accuracy of the measured data. The hardware components of any real-time load-pull system introduce significant distortions and these distortions are mathematically described by a set of numbers called the error coefficients. The error coefficients of a load-pull system are determined by performing an advanced calibration procedure. Once the error coefficients are known, the distortions of the measured data can be removed by a mathematical algorithm. A good reference on a prior art calibration procedure is “An Improved Calibration Technique for On-Wafer Large-Signal Transistor Characterization,” by Andrea Ferrero and Umberto Pisani, IEEE Transactions on Instrumentation and Measurement, Vol. 42, No. 2, pp. 360-364, April 1993. In the following we will present a typical prior art calibration procedure of a real-time load-pull system, as described in the above reference paper.

In a first step one disconnects the tuners from the real-time load-pull system and one replaces the device-under-test 14 by a series of calibration standards. This is illustrated in FIG. 3. Calibration standards are components with characteristics that are accurately known a priori. They are commonly used for the calibration of vector network analyzers. For each calibration standard one sends a signal through the wave sensing structure of the load-pull system and one measures the incident waves as well as the reflected waves, which are generated by the calibration standard in response to the incident waves. The above procedure, although not explicitly mentioned in the reference paper, can be performed at both the input as well as the output test port of the real-time load-pull system. The next step is to connect both test ports by means of a line element 26, typically a through or a line standard element, and to connect a set of calibration standards to the end of the output wave sensing structure 13 that is not connected to the device-under-test 14. This is illustrated in FIG. 4. As in the first step, one then sends a signal through the input wave sensing structure 12, through the line element 26, through the output wave sensing structure 13 and one measures the incident waves as well as the reflected waves, which are caused by the one-port calibration standard 24. Next one repeats the above procedure whereby one replaces the calibration standard 24 by a power sensor 29. This is illustrated in FIG. 5. In advanced cases one also wants to measure the phase of the harmonics that are generated by the device-under-test 14, as described in “Measurements of Time-Domain Voltage/Current Waveforms at RF and Microwave Frequencies Based on the Use of a Vector Network Analyzer for the Characterization of Nonlinear Devices—Application to High-Efficiency Power Amplifiers and Frequency-Multipliers Optimization,” by Denis Barataud et al., IEEE Transactions on Instrumentation and Measurement, Vol. 47, No. 5, pp. 1259-1264, October 1998. The capability to measure the phase of harmonics requires a final calibration step whereby one replaces the power sensor 29 by a harmonic phase reference generator 27. This is illustrated in FIG. 6. The harmonic phase reference generator 27 is usually driven by the same signal source 11 that is used for the other steps of the calibration.

The measured incident and reflected waves, acquired during the calibration procedure, together with the a priori knowledge of the characteristics of the calibration standards, are then used to calculate the error coefficients of the real-time load-pull system. Once the error coefficients are known the tuners are connected to the wave sensing structures of the real-time loadpull system and accurate measurement of the device-under-test 14 behavior can be performed.

Our invention relates to novel method to calibrate high-frequency real-time load-pull systems.

### OBJECT AND ADVANTAGES OF THE PRESENT INVENTION

It is the object of the present invention to simplify the calibration procedure of high-frequency load-pull systems as outlined above. With the novel method one eliminates the need to disconnect the tuner for the purpose of system calibration. This has several significant advantages when compared to the prior art. In the case where the tuners are connected and disconnected by hand, the novel method results in less manipulations. This has two advantages. Firstly, this speeds up the calibration procedure since manual connections and disconnections are time consuming. Secondly it decreases the chance of operator errors, thereby increasing the reliability of the calibration procedure. In case the tuners are connected and disconnected by means of automated switches, the novel method results in a measurement setup with fewer components since the switches can be eliminated. This has two advantages. Firstly, it results in a cost reduction of the measurement system. Secondly it decreases the chance of hardware failure, thereby increasing the reliability of the calibration procedure.

### BRIEF DESCRIPTION OF THE DRAWINGS

FIG. 1 (Prior Art) depicts a simple load-pull system.

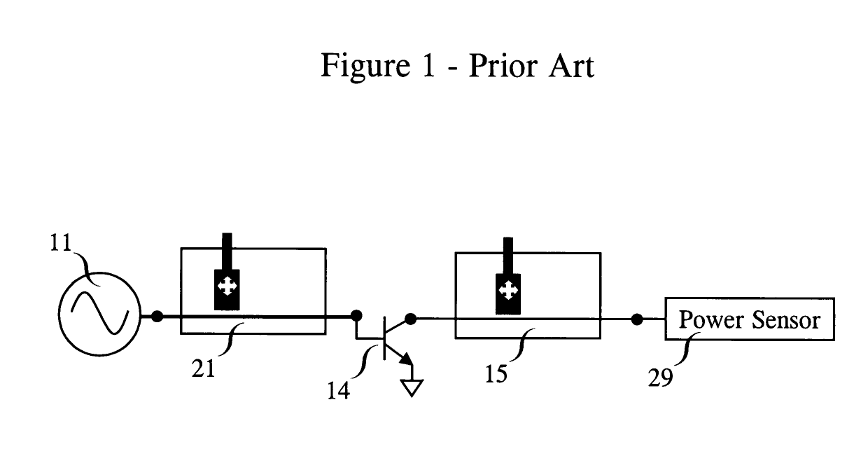

FIG. 2 (Prior Art) depicts a real-time load-pull system.

FIG. 3 (Prior Art) illustrates the first step for calibrating a real-time load-pull system.

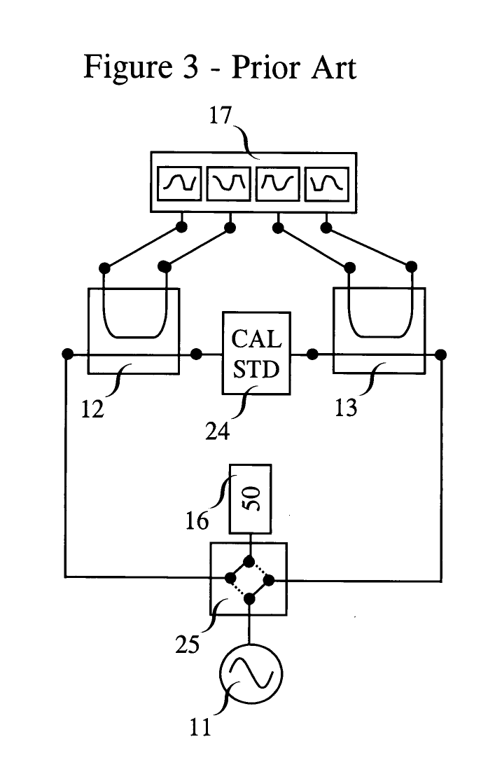

FIG. 4 (Prior Art) illustrates the second step for calibrating a real-time load-pull system.

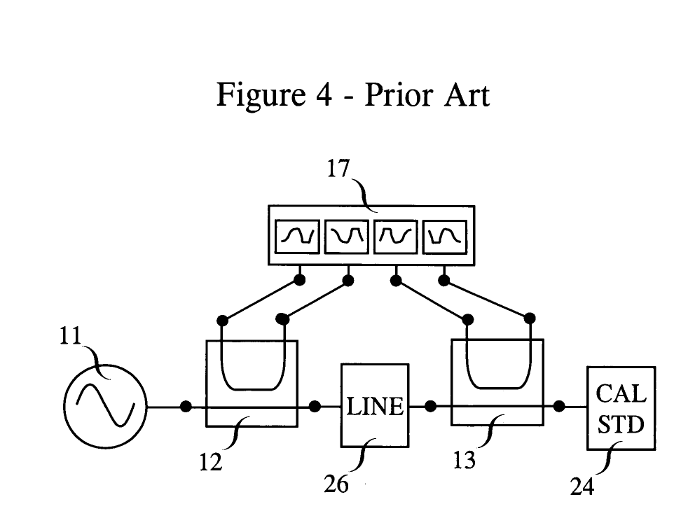

FIG. 5 (Prior Art) illustrates the third step for calibrating a real-time load-pull system.

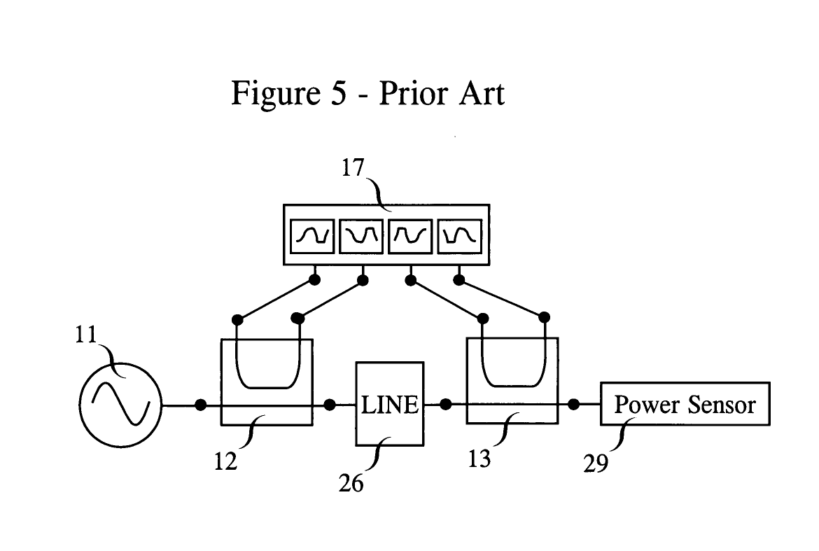

FIG. 6 (Prior Art) illustrates the fourth step for calibrating a real-time load-pull system.

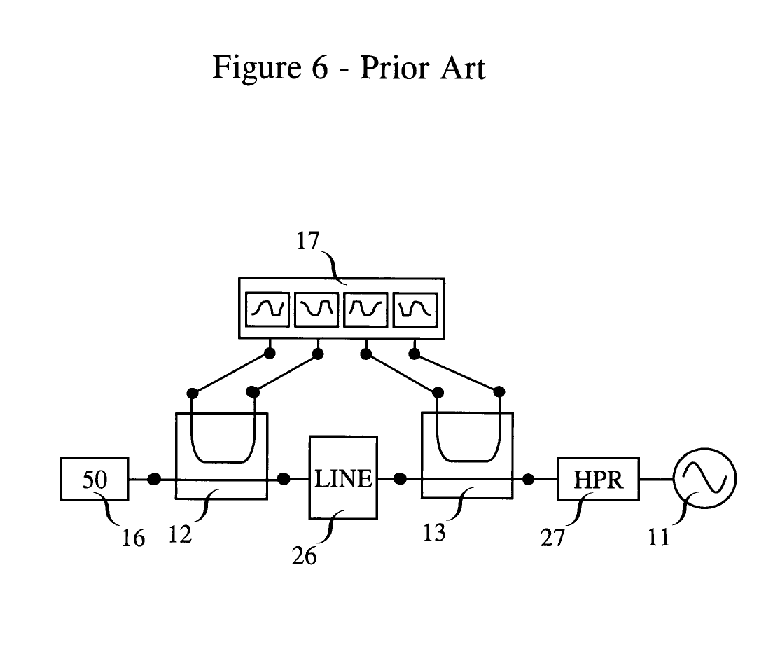

FIG. 7 illustrates the first step of the novel method.

FIG. 8 illustrates the second step of the novel method.

FIG. 9 illustrates the third step of the novel method.

FIG. 10 illustrates the fourth step of the novel method.

FIG. 11 is a detailed flow chart of the novel method.

### DRAWINGS—REFERENCE NUMERALS

11 signal source

12 input wave sensing structure

13 output wave sensing structure

14 device-under-test

15 output tuner

16 matched load

17 receiver

21 input tuner

24 calibration standard

25 calibration switch

26 line element

27 harmonic phase reference generator

28 phase reference switch

29 power sensor

### DETAILED DESCRIPTION

### Preferred Embodiment

The invention was publicly presented by Dr. Jan Verspecht under the title “Affordable Large-Signal Network Analyzer Technology” on Sunday Jan. 7, 2007 at the workshop “RF Power Transistor and Amplifier Characterization Techniques” during the Radio and Wireless Week 2007, Long Beach, USA. The invention is a novel calibration procedure and will be explained in the following. With the novel calibration procedure, the electromagnetic wave signals always pass through the input tuner 21 or the output tuner 15 or both the input tuner 21 and the output tuner 15 of the real-time load-pull system. This is not the case in prior art and is an important novel feature of the present invention that results in significant advantages.

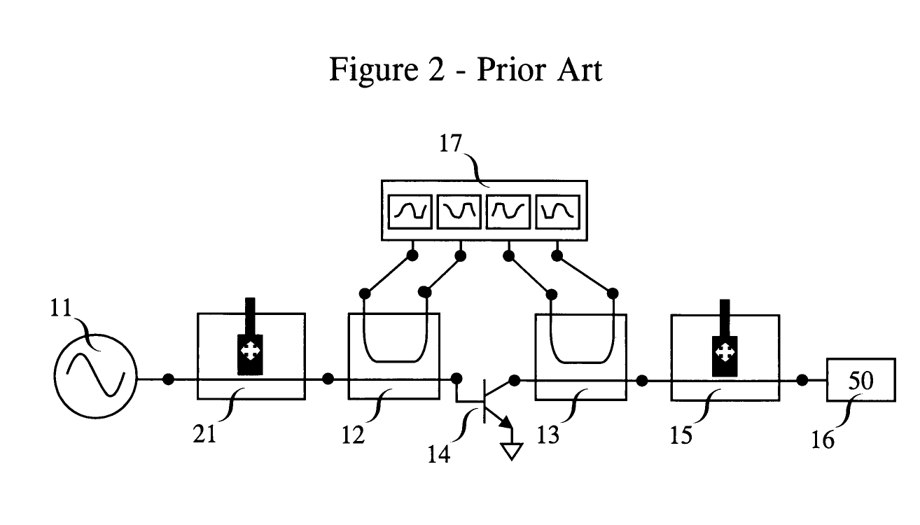

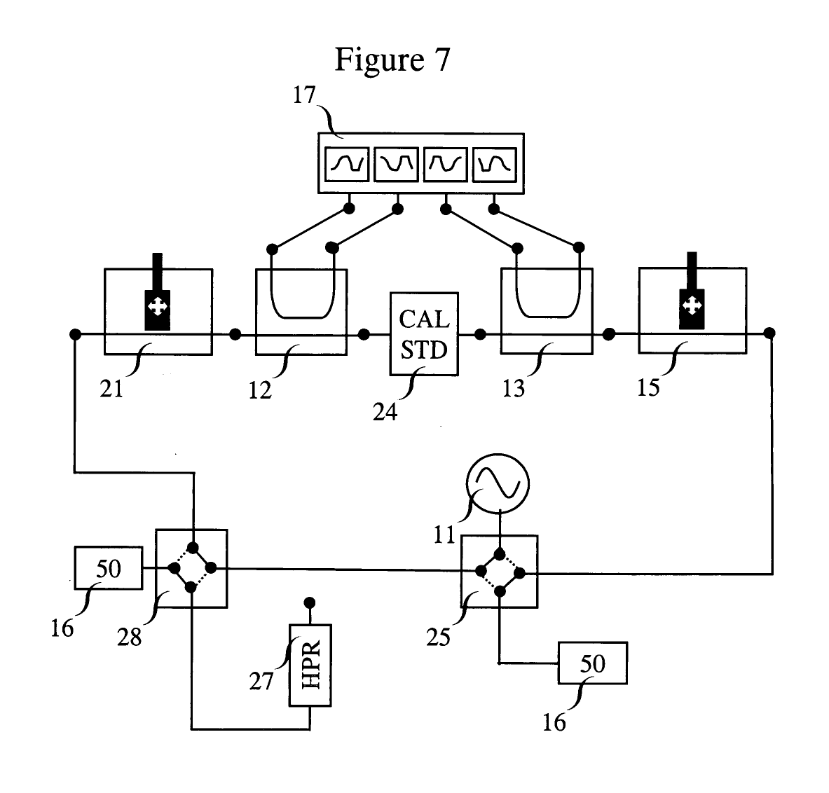

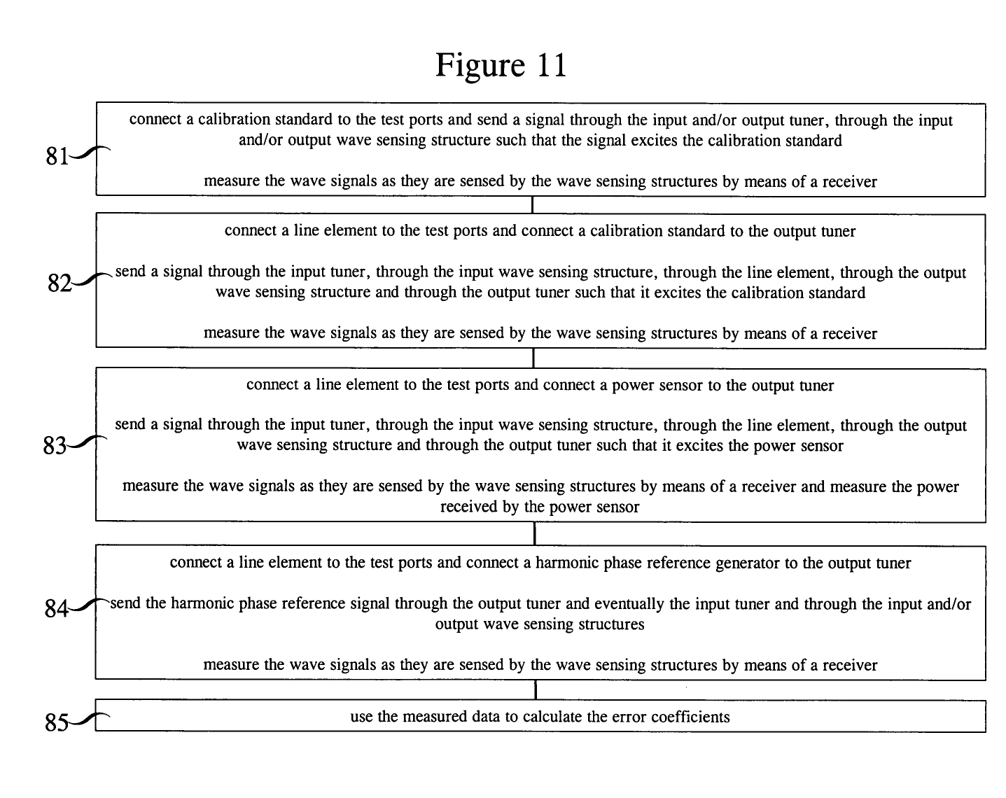

First we will describe the hardware components of a real-time load-pull setup as depicted in FIG. 2. The signal source 11 is connected to the input tuner 21. The input tuner 21 is connected to the input wave sensing structure 12. The other end of the input wave sensing structure 12 is the input test port of the real-time load-pull system. During a regular measurement the input test port is connected to the input terminal of the device-under-test 14. A similar structure is present at the output side of the real-time load-pull system. A matched load 16 is connected to the output tuner 15. The output tuner 15 is connected to the output wave sensing structure 13. The other end of the output wave sensing structure 13 is the output test port of the real-time load-pull system. During a regular measurement the output test port is connected to the output terminal of the device-under-test 14. The matched load 16 can be replaced by a receiver 17 like e.g. a power sensor 29 or a spectrum analyzer. Depending on the tuner technology, it is possible that no matched load 16 is present. There are also real-time load-pull setups that only have an output tuner 15, with no input tuner 21 being present. The preferred embodiment of the novel calibration procedure is illustrated in FIGS. 7 through 10. A calibration switch 25 and a phase reference switch 28 are added to the real-time load-pull system to automate the calibration procedure. Note that the calibration procedure can be performed without automation if one or even both of the switches are eliminated. In that case the functionality of the switch is replaced by manual disconnections and connections. During all of the steps of the novel calibration method the input tuner 21 and the output tuner 15 are usually controlled such that their characteristics are close to those of a line element. Note that the above setting of the tuners is practical but is not essential for the novel calibration procedure. The first step 81 of the novel calibration method is described in FIG. 11 and is depicted in FIG. 7. A calibration standard 24 is connected to the test ports of the real-time load-pull system and the calibration switch 25 and the phase reference switch 28 are set such that the electromagnetic wave signal of the signal source 11 is directed towards the input test port or the output test port of the real-time load-pull system. Note that the calibration standard 24 is often a one port device, in which case it is connected to one test port only and the signal source 11 is directed to the test port connected to the calibration element. The electromagnetic wave signal interacts with the calibration standard 24, resulting in reflected waves. The incident and reflected waves are sensed by the input wave sensing structure 12 and the output wave sensing structure 13 and are finally measured by the receiver 17. The above procedure is then repeated connecting other calibration standards. In a typical case the calibration standards that are used are the same as the ones that are used for common vector network analyzer calibration, namely a line element 26 or thru element and a matched load 16, an open element and a short element, the latter three being connected once to the input test port and once to the output test port.

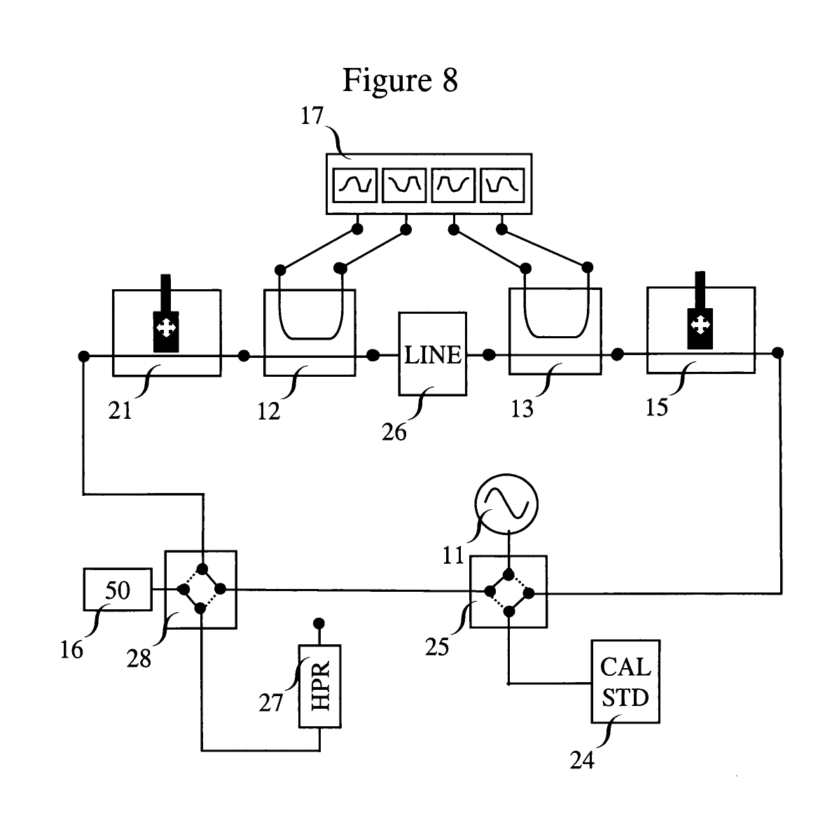

The second step 82 of the novel calibration method is described in FIG. 11 and is depicted in FIG. 8. The test ports of the real-time load-pull system are connected to a line element 26. A calibration standard 24 is connected to the calibration switch 25. The calibration switch 25 and the phase reference switch 28 are set in a position such that the electromagnetic wave signal that is generated by the signal source 11 is directed towards the input tuner 21 of the real-time load-pull system. The electromagnetic wave signal then passes through the input wave sensing structure 12, through the line element 26, through the output wave sensing structure 13, through the output tuner 15, through the calibration switch 25 and finally reaches the calibration standard 24. The electro-magnetic wave signal interacts with the calibration standard 24, resulting in reflected waves. The incident and reflected waves are sensed by the input wave sensing structure 12 or the output wave sensing structure 13 or both the input wave sensing structure 12 and the output wave sensing structure 13 and are finally measured by the receiver 17. The above procedure is then repeated connecting other calibration standards. In a typical case the calibration standards that are used are the one-port calibration standards that are commonly used for vector network analyzer calibration, namely a matched load 16, an open element and a short element.

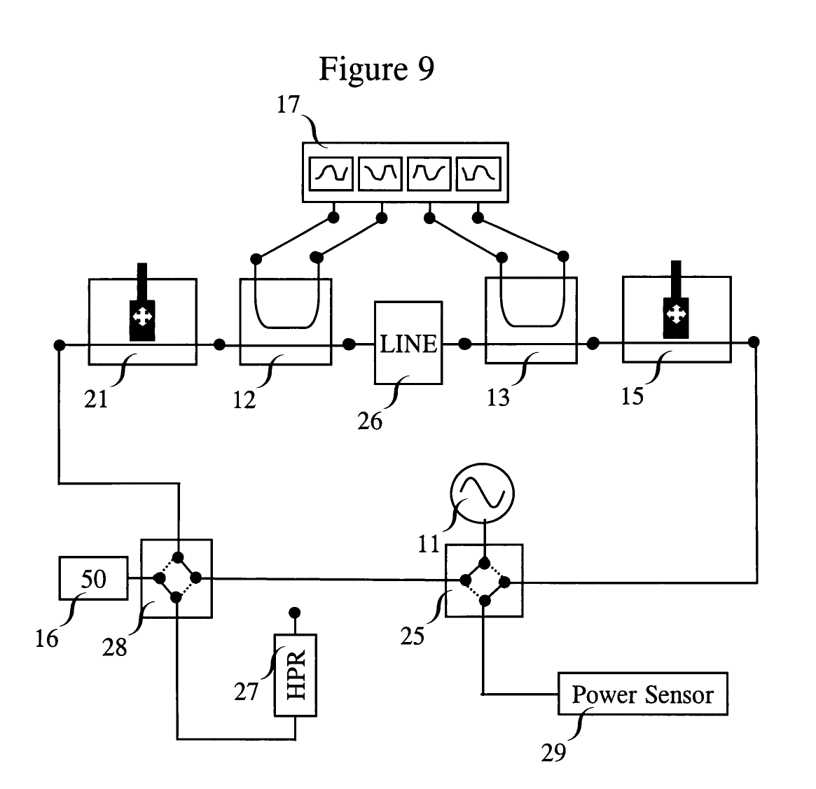

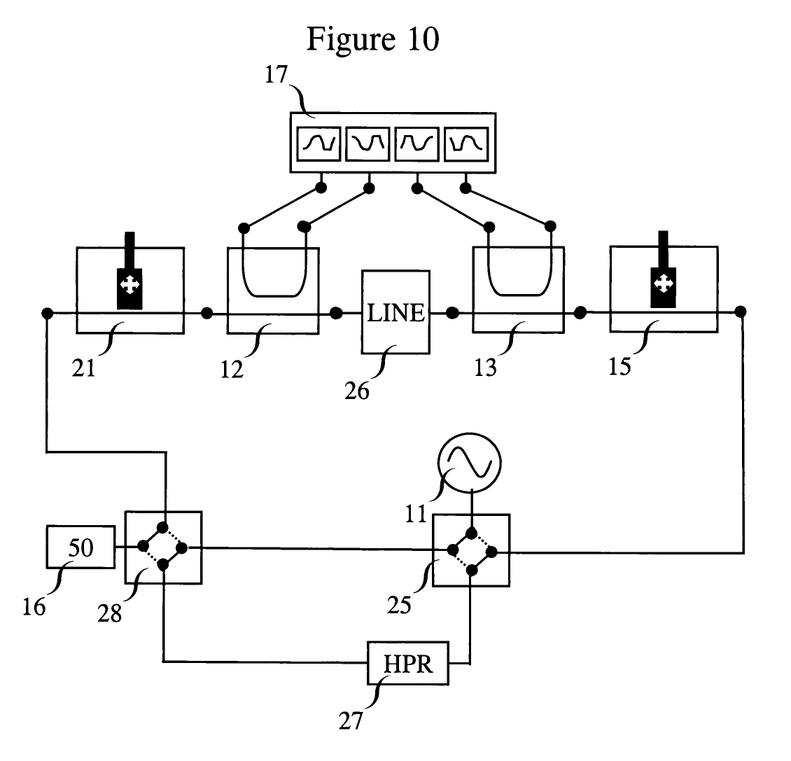

The third step 83 of the novel calibration method is described in FIG. 11 and is depicted in FIG. 9. The step is almost identical to the second step described above, the only difference being that one replaces the calibration element by a power sensor 29. The fourth step 84 of the novel calibration procedure is described in FIG. 11 and is depicted in FIG. 10. The step is almost identical to the second step described above, the only two differences being that one replaces the calibration element by a harmonic phase reference generator 27 and that one sets the phase reference switch 28 such that the signal source 11 excites the input connector of the harmonic phase reference generator 27.

After the fourth step has been completed, the final step 85 is executed and the measured values of the incident and the reflected electromagnetic wave signals are used to calculate the error coefficients of the real-time load-pull system. These error coefficients are used during the measurements to correct for all of the linear distortions that are introduced by the non-ideal hardware of the real-time load-pull system.

### Alternative Embodiments

Any calibration procedure for a real-time load-pull system can be regarded as the extension of a calibration procedure for a vector network analyzer. The extension is mainly the addition of an amplitude calibration based on a power sensor 29 and, in many cases, an harmonic phase calibration based on a harmonic phase reference generator 27. There exist many embodiments of calibration procedures for vector network analyzers in the prior art, and all of those different vector network analyzer calibration procedure embodiments can easily be extended towards real-time load-pull systems by adding an amplitude calibration and, in many cases, a harmonic phase calibration. Any extension of an existing vector network analyzer calibration towards a real-time load-pull system whereby the electromagnetic wave signal passes through the input tuner 21 or the output tuner 15 during the calibration is an alternative embodiment of the present invention.

Any person skilled in the art can also easily replace the functionality of the phase reference switch 28 and the calibration switch 25 by other switch configurations or by manual connections and disconnections. The calibration switch 25 and the phase reference switch 28 depicted in FIGS. 7 through 10 are of the switch type called “double pole double throw,” often referred to as DPDT switch. Any person skilled in the art can easily build a configuration using different switch types that results in the same functionality. All variations of the calibration procedure whereby the configuration of the switches is different or whereby another switch type or no switches are being used and whereby the signal passes through one of the tuners are alternative embodiments of the present invention.

In some cases the second, third and fourth step, whereby a line element is connected to the test ports, can be replaced by simply repeating the first step and sequentially replacing the calibration standard by the power sensor 29 and the harmonic phase reference generator 27. This method can only be applied in the case where the test ports have a connection terminal that is compatible with the connection terminal of the power sensor as well as with the connection terminal of the harmonic phase reference generator. In many cases this is not possible because the connection terminals of the test ports are wafer probes and because no power sensors or harmonic phase reference generators are readily available on wafer.

The order of the different steps of the novel calibration procedure can be arbitrarily changed without affecting the result of the method. Many alternative embodiments are as such constructed by simply changing the order of the calibration steps.

### ADVANTAGES OF THE PRESENT INVENTION

The present invention has the following advantages, which are not present in any system described in the prior art. With the novel method one eliminates the need to disconnect the tuner for the purpose of system calibration. This has several significant advantages when compared to the prior art. In the case where the tuners are connected and disconnected by hand, the novel method results in less manipulations. This has two advantages. Firstly, this speeds up the calibration procedure since manual connections and disconnections are time consuming. Secondly it decreases the chance of operator errors, thereby increasing the reliability of the calibration procedure. In case the tuners are connected and disconnected by means of automated switches, the novel method results in a measurement setup with fewer components since the switches can be eliminated. This has two advantages. Firstly, it results in a cost reduction of the measurement system. Secondly it decreases the chance of hardware failure, thereby increasing the reliability of the calibration procedure.

What is claimed is:

1. A method for calibrating a load-pull system comprising the step of sending an electromagnetic wave signal through a tuner of said load-pull system.

2. Said method of claim 1 wherein said load-pull system is a real-time load-pull system.

3. Said method of claim 2 wherein said load-pull system is calibrated for a set of frequencies that are harmonically related.

4. A method for calibrating said load-pull system, comprising the steps of:
a. connecting a calibration standard to a test port of said load-pull system,
b. guiding an incident electromagnetic wave signal through a tuner of said load-pull system towards a wave sensing structure of said load-pull system,
c. guiding said incident electromagnetic wave signal through said wave sensing structure of said load-pull system towards said calibration standard, whereby said calibration standard generates a reflected electromagnetic wave signal,
d. sensing said incident electromagnetic wave signal by means of said wave sensing structure,
e. sensing said reflected electro-magnetic wave signal by means of said wave sensing structure.

5. A method wherein said method of claim 4 is repeated for a multitude of calibration standards.

6. A method wherein said method of claim 5 is repeated at a multitude of test ports of said load-pull system.

7. Said method of claim 5, further comprising the step of using said sensed incident electromagnetic wave signal and said sensed reflected electromagnetic wave signal to determine the error coefficients of said load-pull system.

8. Said method of claim 6, further comprising the step of using said sensed incident electromagnetic wave signal and said sensed reflected electromagnetic wave signal to determine the error coefficients of said load-pull system.
